(19) United States
(12) Patent Application Publication
(10) Pub. No.: US 2008/0266007 A1
(43) Pub. Date: Oct. 30, 2008

(54) OSCILLATING APPARATUS HAVING CURRENT COMPENSATING DEVICE FOR PROVIDING COMPENSATING CURRENT TO COMPENSATE FOR CURRENT REDUCTION OF TRANSCONDUCTIVE DEVICE AND METHOD THEREOF

(76) Inventor: Ming-Da Tsai, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/740,282

(22) Filed: Apr. 25, 2007

(51) Int. Cl. H03B 5/12; H03L 5/00

(52) U.S. Cl. 331/117 FE

(57) ABSTRACT

According to an embodiment of the present invention, an oscillating apparatus is provided. The oscillating apparatus generates an oscillating signal, and the oscillating apparatus includes a resonating device, a transconductive device, a biasing device, and a current compensating device. The resonating device generates the oscillating signal; the transconductive device is coupled to the resonating device for providing the resonating device with a positive feedback loop; the biasing device is coupled to the transconductive device for providing the transconductive device with a biasing current; and the current compensating device is coupled between the resonating device and the biasing device for providing the biasing device with a compensating current to compensate for a current reduction of the transconductive device.

### BACKGROUND

The present invention relates to an LC tank oscillator, and more particularly, to a low phase noise LC tank oscillator and related method to reduce the phase noise of an oscillating signal generated from the LC tank oscillator.

Phase noise is an inherent problem in the design of wireless communication circuitry. It is mainly due to noise generated by MOS transistors used with a tuning circuit for sustaining oscillations in the oscillator circuitry, and is considered to be due to modulation from the 1/f baseband noise spectrum of the nonlinear transfer characteristic and limiting behavior of the MOS transistor. This phase noise is conventionally reduced by the filtering effect of a resonant tank circuit. The effectiveness in reducing phase noise is dependent on the loaded quality factor Q, in which the quality factor Q indicates energy lost per cycle relative to total stored energy in the resonant tank circuit. The energy lost per cycle is energy dissipated by the reactive elements. The energy output is used to promote the oscillation of the oscillator. Losses due to tuning elements of the resonant tank circuit, such as varactor diodes used in the voltage controlled oscillators, are a primary factor in reducing the quality factor Q. Therefore, the loaded quality factor Q of the resonant tank circuit can determine the ability of filtering the phase noise.

Please refer to FIG. 1. FIG. 1 is a diagram illustrating a related art LC VCO 10 (Inductive/capacitive voltage-controlled oscillator). The LC VCO comprises a LC resonator 11, cross-coupled NMOS transistors M1, M2, and a tail current source 12. The LC resonator 11 comprises two inductors L1, L2, and a capacitor C1. The tail current source 12 comprises an NMOS transistor M3. Furthermore, the related art LC VCO 10 that employs the tail current source 12 can provide better common-mode rejection (i.e. less sensitive to supply voltage or ground voltage common-mode fluctuation). Furthermore, the process corner variation of the related art LC VCO using the tail current source is smaller than the voltage-biased VCO. The main contributors to the phase noise of the related art LC VCO 10 are the cross-coupled NMOS transistors M1, M2, the tail current source 12, and the node noise associated with the loss in the LC resonator 11, in which, the noise contribution due to the tail current source 12 might worsen the phase noise of the related art LC VCO 10. On the other hand, the thermal noise contributed by the LC resonator 11 can be reduced by using inductors, capacitors and varactors which have a high quality factor Q. However, the maximum achievable quality factor Q for passive components is mainly determined by technology limitations and can only be slightly improved by design or layout techniques. As a result, the aforementioned filtering techniques were to reduce the contribution of the tail current source 12 to the phase noise. However, most of the tail current filter techniques are focused on filtering the noise at the second harmonic and they often consume large circuit/chip areas.

According to the reference of Babak Soltanian and Peter R. Kingset, “Tail Current-Shaping to Improve Phase Noise in LC Voltage-Controlled Oscillators,” IEEE JOURNAL OF SOLID-STATE CIRCUITS, VOL. 41, NO. 8, AUGUST 2006, a conventional scheme of introducing a tail-current shaping technique in LC-VCOs to increase the amplitude and to reduce the phase noise while keeping the power dissipation constant is provided. According to this conventional scheme, the tail current is made large when the oscillator output voltage reaches its maximum or minimum value and when the sensitivity of the output phase to injected noise is the smallest; tail current is made small during the zero crossing of the output voltage when the phase noise sensitivity is large. Accordingly, the phase noise due to the active devices can be reduced, and the VCO has a more larger oscillation amplitude and thus better DC to RF conversion, compared to a typical VCO with equal power dissipation.

According to another reference of B. D. Muer, M. Borremans, M. Steyaert, and G. L. Puma, “A 2-GHz Low-Phase-Noise Integrated LC-VCO Set with Flicker-Noise Up-conversion Minimization,” IEEE JOURNAL OF SOLID-STATE CIRCUITS, VOL. 35, NO. 7, JULY 2000, another conventional scheme of minimizing the phase noise by up-converting the flicker noise generated by the LC-VCO is provided. This conventional scheme defines a flicker-noise up-conversion factor to minimize the up-conversion of the flicker noise to 1/f³ phase noise.

According to yet another reference of A. Hajimiri and T. H. Lee, “Design issues in CMOS differential LC oscillators,” IEEE JOURNAL OF SOLID-STATE CIRCUITS, VOL. 34, pp. 717-724, MAY 1999, another conventional scheme of lowering the phase noise factor in a differential oscillator is provided. This conventional scheme arranges a large capacitor in parallel with the current source of an LC oscillator to shrink the duty cycle of switching current in the differential pair, which lowers the instantaneous FET current at differential zero crossing, thus lowering the phase noise due to the differential-pair FETs.

### SUMMARY OF THE INVENTION

Therefore, one of the objectives of an embodiment of the present invention is to provide an LC tank oscillator and method to reduce the phase noise of an oscillating signal generated from the LC tank oscillator.

According to an embodiment of the present invention, an oscillating apparatus is provided. The oscillating apparatus generates an oscillating signal, and the oscillating apparatus comprises: a resonating device, a transconductive device, a biasing device, and a current compensating device. The resonating device generates the oscillating signal; the transconductive device is coupled to the resonating device for providing the resonating device with a positive feedback loop; the biasing device is coupled to the transconductive device for providing the transconductive device with a biasing current; and the current compensating device is coupled between the resonating device and the biasing device for providing the biasing device with a compensating current to compensate for a current reduction of the transconductive device.

According to another embodiment of the present invention, a method for reducing a phase noise of an oscillating signal generated from an oscillating apparatus is provided. The method comprises the steps of: designing the oscillating apparatus to have a resonating device for generating the oscillating signal, a transconductive device for providing the resonating device with a positive feedback loop, and a biasing device for providing the transconductive device with a biasing current; and directly connecting a common mode node of the resonating device and a common mode node of the transconductive device.

According to yet another embodiment of the present invention, a method for reducing a phase noise of an oscillating signal generated from an oscillating apparatus is provided. The method comprises the steps of: designing the oscillating apparatus to have a resonating device for generating the oscillating signal, a transconductive device for providing the resonating device with a positive feedback loop, and a biasing device for providing the transconductive device with a biasing current; and coupling an inductive device between a common mode node of the resonating device and a common mode node of the transconductive device.

According to yet another embodiment of the present invention, a method for reducing a phase noise of an oscillating signal generated from an oscillating apparatus is provided. The method comprises the steps of: designing the oscillating apparatus to have a resonating device for generating the oscillating signal, a transconductive device for providing the resonating device with a positive feedback loop, and a biasing device for providing the transconductive device with a biasing current; and coupling a capacitive device between a common mode node of the resonating device and a common mode node of the transconductive device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a related art LC VCO.

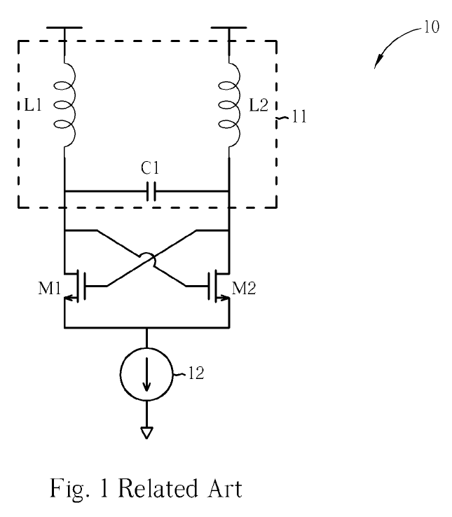

FIG. 2 is a diagram illustrating an oscillating apparatus according to a first embodiment of the present invention.

FIG. 3 is a timing diagram illustrating the oscillating signal, the compensating current, the biasing current, and an effective current of the oscillating apparatus shown in FIG. 2.

FIG. 4 is a diagram illustrating the phase noises of the oscillating apparatus shown in FIG. 2 and the prior art.

FIG. 5 is a diagram illustrating a second embodiment of the oscillating apparatus of the present invention.

FIG. 6 is a diagram illustrating a third embodiment of the oscillating apparatus of the present invention.

FIG. 7 is a diagram illustrating a fourth embodiment of the oscillating apparatus of the present invention.

FIG. 8 is a diagram illustrating a fifth embodiment of the oscillating apparatus of the present invention.

FIG. 9 is a diagram illustrating a sixth embodiment of the oscillating apparatus of the present invention.

FIG. 10 is a flow chart illustrating a method for reducing a phase noise of an oscillating signal generated from an oscillating apparatus.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

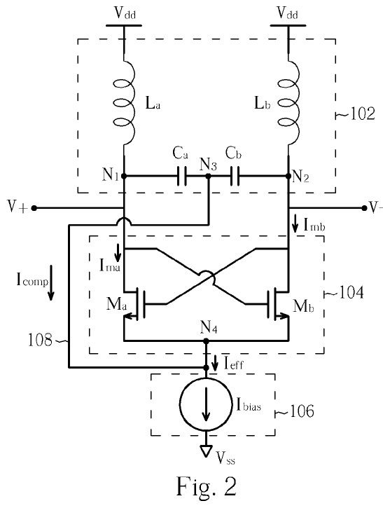

Please refer to FIG. 2. FIG. 2 is a diagram illustrating an oscillating apparatus 100 according to a first embodiment of the present invention. The oscillating apparatus 100 comprises a resonating device 102, a transconductive device 104, a biasing device 106, and a current compensating device 108. The resonating device 102 generates an oscillating signal S_{osc}. The transconductive device 104 is coupled to the resonating device 102, and configured for providing the resonating device 102 with a positive feedback loop. The biasing device 106 is coupled to the transconductive device 104, and configured for providing the transconductive device 104 with a biasing current I_{bias}. The current compensating device 108 is coupled between the resonating device 102 and the biasing device 106, and configured for providing the biasing device 106 with a compensating current I_{comp} to compensate for a current reduction of the transconductive device 104.

In this embodiment, the resonating device 102 comprises inductors Lₐ, L_{b}, and capacitors Cₐ, C_{b}, in which, the inductor Lₐ has one node coupled to a supply voltage V_{dd} and the other node N₁ coupled to a node of the capacitor Cₐ, the inductor L_{b} has one node coupled to the supply voltage V_{dd} and the other node N₂ coupled to a node of the capacitor C_{b}. As shown in FIG. 2, the capacitor Cₐ connects to the capacitor C_{b} at node N₃. Furthermore, the transconductive device 104 comprises a first NMOS transistor Mₐ and a second NMOS transistor M_{b} that are cross-coupled with each other. In addition, the gate node of the transistor Mₐ is coupled to the node N₂ and the gate node of the transistor M_{b} is coupled to the node N₁, in which the nodes N₁ and N₂ output the differential oscillating signal (i.e. an oscillating signal S_{osc}). The biasing device 106 is a current source having a node N₄ coupled to the common source node of the first NMOS transistor Mₐ and the second NMOS transistor M_{b} for generating the biasing current I_{bias} to the first NMOS transistor Mₐ and the second NMOS transistor M_{b}, and the other node of the current source coupled to the ground voltage V_{dd}. In this embodiment, the current compensating device 108 is simply implemented by a conductive line having a first node directly connected to a common mode node (i.e. node N₃) of the resonating device 102 and a second node directly connected to the common mode node (i.e. node N₄) of the transconductive device 104.

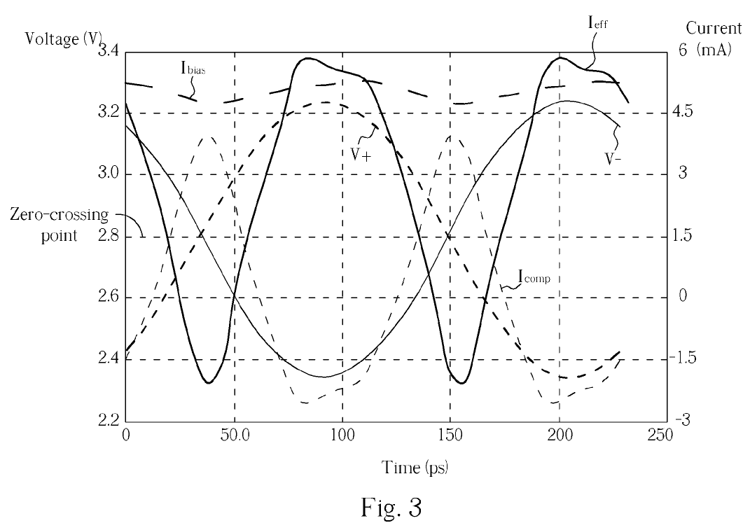

When the positive feedback condition between the transconductive device 104 and the resonating device 102 is held, the oscillating apparatus 100 generates the oscillating signal S_{osc}. Please note that the hardware settings of the inductors Lₐ, L_{b}, capacitors Cₐ, C_{b}, NMOS transistors Mₐ, M_{b}, and the biasing current I_{bias} are well-known to those skilled in this art, thus a detailed description is omitted here for brevity. Furthermore, in order to describe the spirit of the embodiment of the present invention in more detail, the frequency of the oscillating signal S_{osc} is assumed to be fₒ, and the oscillating signal S_{osc} is composed of a first output signal V+ and a second output signal V− outputted at nodes N₁ and N₂ respectively. Please refer to FIG. 3. FIG. 3 is a timing diagram illustrating the oscillating signal S_{osc}, the compensating current I_{comp}, the biasing current I_{bias}, and an effective current I_{eff}, wherein the effective current I_{eff} is the effective current of the sources of the NMOS transistors Mₐ and M_{b} at node N₄. In other words, the effective current I_{eff} is the sum of currents Iₘₐ and I_{mb}.

When the oscillating apparatus 100 is operating, the first output signal V+ swings in the frequency fₒ at the node N₁, while the inversed signal (i.e. the second output signal V−) swings in the frequency fₒ at the node N₂; therefore the voltage at the node N₃ is the common mode voltage of the oscillating signal S_{osc} if the configuration of the oscillating apparatus 100 is symmetrical. In addition, the common mode voltage at the node N₃ is the zero-crossing point of the oscillating signal S_{osc} as shown in FIG. 3. As to the voltage around the zero-crossing point, both the NMOS transistors Mₐ, M_{b} are approximately turned off or completely turned off, depending on the design of the oscillating apparatus 100. This results in the effective current I_{eff} being close to zero. In other words, the currents Iₘₐ and I_{mb} are close to zero. As the biasing current I_{bias} is not ideal in practice, the biasing current I_{bias} will decrease in the frequency of 2*fₒ if there is no supplementary current injected into the node N₄. On the other hand, the inductor current I_{La} and the inductor current I_{Lb} still exist while the currents Iₘₐ and I_{mb} are close to zero. Therefore, according to the embodiment of the present invention, the current compensating device 108 is configured to provide a current path to supply an injection current (i.e. the compensating current I_{comp}) to the node N₄. Accordingly, the biasing current I_{bias} can remain substantially constant. Therefore, the embodiment of the present invention reuses the current of the resonating device 102 through the current compensating device 108 in the frequency of 2*fₒ. In other words, the biasing current I_{bias} can be viewed as either supplied by the current Iₘₐ, the current I_{mb}, or the compensating current I_{comp}.

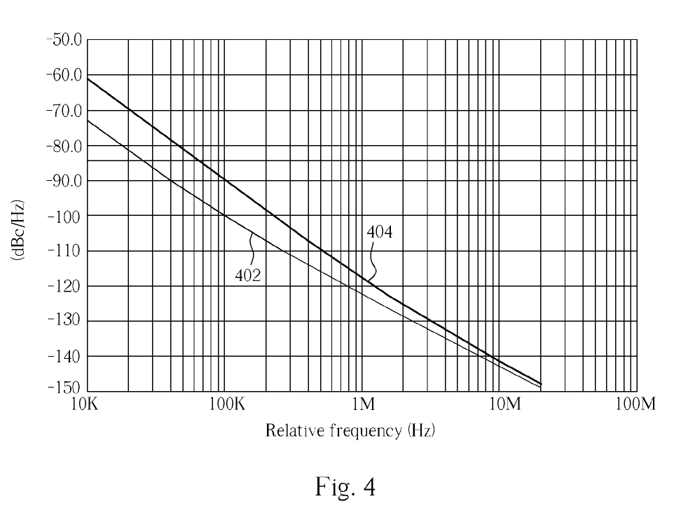

As known by those skilled in this art, the phase noise of the oscillating apparatus 100 is dominated by the flicker noise of the NMOS transistors Mₐ, M_{b} of the resonating device 102 when operating. In this embodiment, there is much less current flowing through the NMOS transistors Mₐ, M_{b}; thus the resulting phase noise of the oscillating apparatus 100 of the present invention is much lower than those conventional oscillating apparatus. Please refer to FIG. 4. FIG. 4 is a diagram illustrating the comparison between the phase noise of the oscillating apparatus 100 of the present invention and the related art oscillating apparatus. In this embodiment, the transconductance values (i.e. gm) of the NMOS transistors Mₐ, M_{b} are set to 19.14 mS, the biasing current I_{bias} is set to 5 mA, the curve 402 represents the phase noise of the oscillating apparatus 100 of the present invention, and the curve 404 represents the phase noise of a conventional oscillating apparatus utilizing the aforementioned tail current shaping method. As one can see, the phase noise of the oscillating apparatus 100 is much less than that of the conventional oscillating apparatus. On the other hand, in this embodiment, the phase noise contribution of the NMOS transistors Mₐ, and M_{b} are 9.91% and 10.51% of the total phase noise (i.e. the curve 402) of the oscillating apparatus 100, while the phase noise contribution of the transistors that have the same role in the conventional art are 45.66% and 45.86% of the total phase noise (i.e. the curve 404) of the related art LC-VCO; therefore, a better phase noise performance of the LC-VCO can be obtained according to the above exemplary embodiment of the present invention.

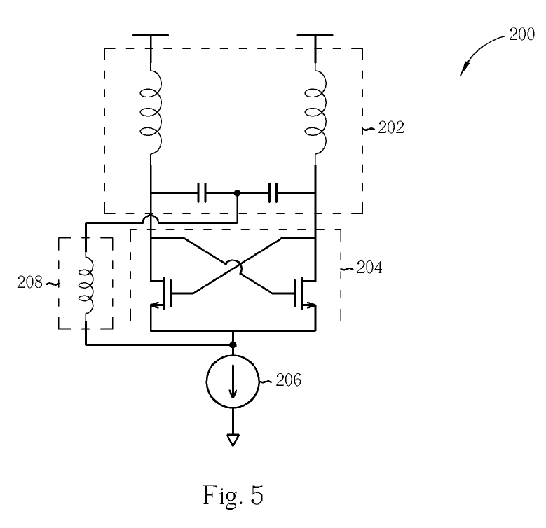

Please refer to FIG. 5. FIG. 5 is a diagram illustrating an oscillating apparatus 200 according to a second embodiment of the present invention. The oscillating apparatus 200 comprises a resonating device 202, a transconductive device 204, a biasing device 206, and a current compensating device 208. The current compensating device 208 comprises an inductor. Similar to the aforementioned embodiment, the inductor has one node directly connected to a common mode node of the resonating device 202 and the other node directly connected to the common mode node of the transconductive device 204. The inductor of the current compensating device 208 is implemented to provide a current path to supply an injection current to the biasing current generated by the biasing device 206 to keep the biasing current at a substantially constant level. Please note that, as the oscillating apparatus 200 is similar to the oscillating apparatus 100, and those skilled in this art will readily understand the operation of the oscillating apparatus 200 after reading the disclosure of the embodiment of the oscillating apparatus 100, further description is omitted here for brevity.

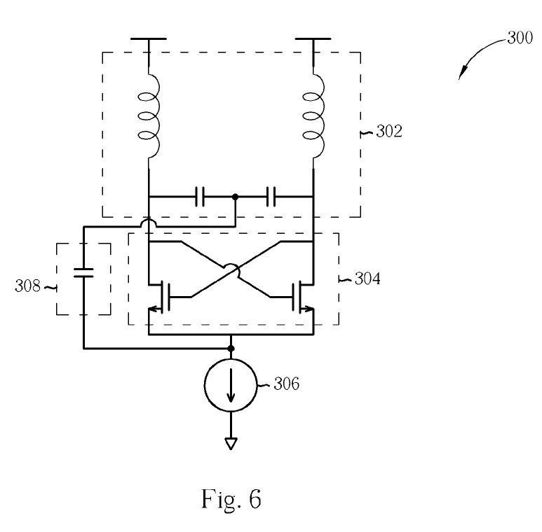

Please refer to FIG. 6. FIG. 6 is a diagram illustrating an oscillating apparatus 300 according to a third another embodiment of the present invention. The oscillating apparatus 300 comprises a resonating device 302, a transconductive device 304, a biasing device 306, and a current compensating device 308. The current compensating device 308 comprises a capacitor. Similar to the aforementioned embodiments, the capacitor has a node directly connected to a common mode node of the resonating device 302 and the other node directly connected to the common mode node of the transconductive device 304. The capacitor of the current compensating device 308 is implemented to provide a current path to supply an injection current to the biasing current generated by the biasing device 306 to keep the biasing current at a substantially constant level. Please note that, as the oscillating apparatus 300 is similar to the oscillating apparatus 100, and those skilled in this art will readily understand the operation of the oscillating apparatus 200 after reading the disclosure of the embodiment of the oscillating apparatus 100, further description is omitted here for brevity.

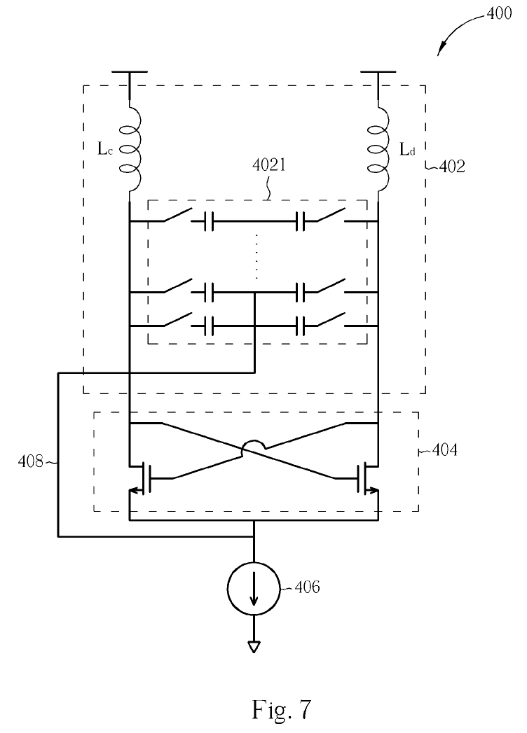

In addition, it should be noted that the resonating device of the present invention can be any kind of LC tank resonator. For example, one of the embodiments of the present invention utilizes a switching capacitor bank to form the LC tank resonator for tuning the oscillating frequency of the oscillating apparatus. However, this is for illustrative purposes only, and not meant to be a limitation of the present invention. Please refer to FIG. 7. FIG. 7 is a diagram illustrating an oscillating apparatus 400 according to a fourth embodiment of the present invention. The oscillating apparatus 400 comprises a resonating device 402, a transconductive device 404, a biasing device 406, and a current compensating device 408. The resonating device 402 comprises inductors L_{c}, L_{d}, and a capacitor tank 4021. The capacitor tank 4021 comprises a plurality of switching capacitor groups. Each switching capacitor group comprises two switches and two capacitors, and the connection is shown in FIG. 7, in which, the current compensating device 408 has one node coupled to each connection node of the two capacitors and has the other node directly connected to the common mode node of the transconductive device 404 as shown in FIG. 7. Please note that, as the oscillating apparatus 400 is similar to the oscillating apparatus 100, and those skilled in this art will readily understand the operation of the oscillating apparatus 400 after reading the disclosure of the embodiment of the oscillating apparatus 100, further description is omitted here for brevity.

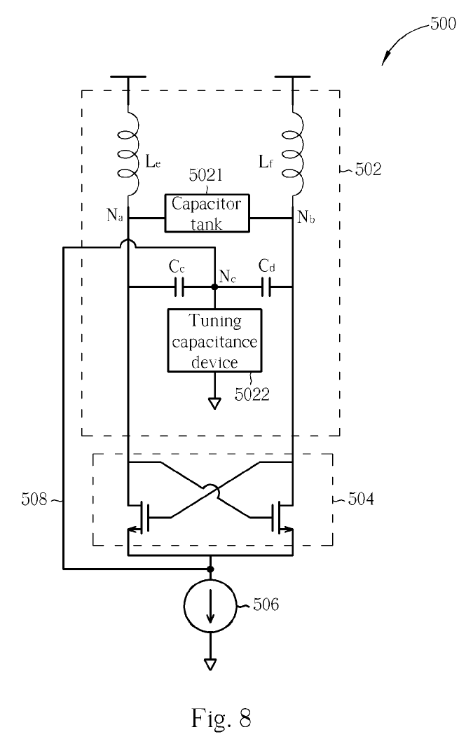

Please refer to FIG. 8. FIG. 8 is a diagram illustrating an oscillating apparatus 500 according to a fifth embodiment of the present invention. The oscillating apparatus 500 comprises a resonating device 502, a transconductive device 504, a biasing device 506, and a current compensating device 508. The resonating device 502 comprises inductors Lₑ, L_{f}, a capacitor tank 5021, capacitors C_{c}, C_{d}, and a tuning capacitance device 5022, in which, the inductor Lₑ has one node coupled to a supply voltage V_{dd} and the other node Nₐ coupled to a node of the capacitor C_{c}, the inductor L_{f} has one node coupled to the supply voltage V_{dd} and the other node N_{b} coupled to a node of the capacitor C_{d}. Additionally, the capacitor C_{c} connects to capacitor C_{d} at node N_{c}. The capacitor tank 5021 is coupled between the nodes Nₐ and N_{b}. The tuning capacitance device 5022 is coupled to the node N_{c}, in which, the current compensating device 508 has a node directly connected to the node N_{c} and C_{d} and has the other node directly connected to the common mode node of the transconductive device 504 as shown in FIG. 8. Please note that, as the oscillating apparatus 500 is similar to the oscillating apparatus 100, and those skilled in this art will readily understand the operation of the oscillating apparatus 500 after reading the disclosure of the embodiment of the oscillating apparatus 100, further description is omitted here for brevity.

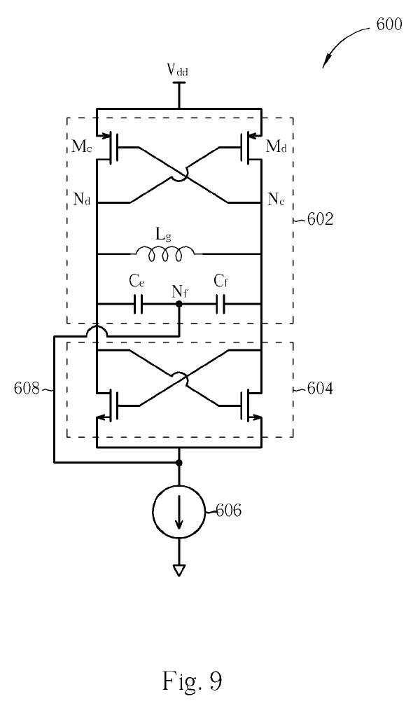

Please refer to FIG. 9. FIG. 9 is a diagram illustrating an oscillating apparatus 600 according to a sixth embodiment of the present invention. The oscillating apparatus 600 comprises a resonating device 602, a transconductive device 604, a biasing device 606, and a current compensating device 608. The resonating device 602 comprises inductor L_{g}, capacitors Cₑ, C_{f}, and cross-coupled NMOS transistors M_{c} and M_{d}, in which, the cross-coupled NMOS transistors M_{c} and M_{d} have a common source terminal coupled to the supply voltage V_{dd}, a gate terminal of the NMOS transistor M_{d} is coupled to a node of the inductor L_{g}, and a gate terminal of the NMOS transistor M_{c} is coupled to another node Nₑ of the inductor L_{g}. In this embodiment, a node of capacitor Cₑ is coupled to node N_{d} and a node of capacitor C_{f} is coupled to node Nₑ, and the capacitor Cₑ connects to the capacitor C_{f} at node N_{f}, in which, the current compensating device 608 has one node directly connected to the node N_{f} and has the other node directly connected to the common mode node of the transconductive device 604 as shown in FIG. 9. Please note that, as the oscillating apparatus 600 is similar to the oscillating apparatus 100, and those skilled in this art will readily understand the operation of the oscillating apparatus 600 after reading the disclosure of the embodiment of the oscillating apparatus 100, further description is omitted here for brevity.

Please note that, although the above-mentioned embodiments of the present invention are based on the NMOS transconductive devices, those skilled in this will readily comprehend that the PMOS transconductive device also falls within the scope of the present invention through appropriate modification of the above-mentioned embodiments.

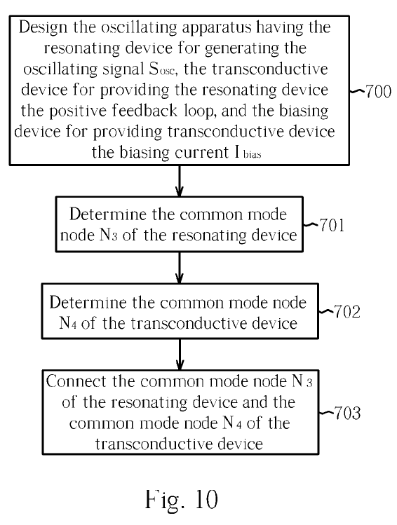

Please refer to FIG. 10. FIG. 10 is a flow chart illustrating a method for reducing a phase noise of an oscillating signal generated from an oscillating apparatus. The method can be described in conjunction with the embodiment of the oscillating apparatus 100 shown in FIG. 2, and is summarized as below:
Step 700: Design the oscillating apparatus 100 having the resonating device 102 for generating the oscillating signal S_{osc}, the transconductive device 104 for providing the resonating device 102 with the positive feedback loop, and the biasing device 106 for providing the transconductive device 104 with the biasing current I_{bias};
Step 701: Determine the common mode node N₃ of the resonating device 102;
Step 702: Determine the common mode node N₄ of the transconductive device 104; and
Step 703: Connect the common mode node N₃ of the resonating device 102 and the common mode node N₄ of the transconductive device 104.

Please note that, in step 702, another embodiment of the present invention utilizes an inductive device to connect the common mode node N₃ of the resonating device 102 and the common mode node N₄ of the transconductive device 104, and another embodiment of the present invention utilizes a capacitive device to connect the common mode node N₃ of the resonating device 102 and the common mode node N₄ of the transconductive device 104.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An oscillating apparatus, for generating an oscillating signal, the oscillating apparatus comprising:
a resonating device, for generating the oscillating signal;
a transconductive device, coupled to the resonating device, for providing the resonating device with a positive feedback loop;
a biasing device, coupled to the transconductive device, for providing the transconductive device with a biasing current; and
a current compensating device, coupled between the resonating device and the biasing device, for providing the biasing device with a compensating current to compensate for a current reduction of the transconductive device.

2. The oscillating apparatus of claim 1, wherein the current compensating device generates a periodic current corresponding to the oscillating signal as the compensating current.

3. The oscillating apparatus of claim 1, wherein the current compensating device is a conductive line having a first node directly connected to a common mode node of the resonating device and a second node directly connected to the common mode node of the transconductive device.

4. The oscillating apparatus of claim 1, wherein the current compensating device is an inductive device having a first node coupled to a common mode node of the resonating device and a second node coupled to the common mode node of the transconductive device.

5. The oscillating apparatus of claim 1, wherein the current compensating device is a capacitive device having a first node coupled to a common mode node of the resonating device and a second node coupled to the common mode node of the transconductive device.

6. A method for reducing a phase noise of an oscillating signal generated from an oscillating apparatus, comprising:
designing the oscillating apparatus to have a resonating device for generating the oscillating signal, a transconductive device for providing the resonating device with a positive feedback loop, and a biasing device for providing the transconductive device with a biasing current; and
directly connecting a common mode node of the resonating device and a common mode node of the transconductive device.

7. A method for reducing a phase noise of an oscillating signal generated from an oscillating apparatus, comprising:
designing the oscillating apparatus to have a resonating device for generating the oscillating signal, a transconductive device for providing the resonating device with a positive feedback loop, and a biasing device for providing the transconductive device with a biasing current; and
coupling an inductive device between a common mode node of the resonating device and a common mode node of the transconductive device.

8. A method for reducing a phase noise of an oscillating signal generated from an oscillating apparatus, comprising:
designing the oscillating apparatus to have a resonating device for generating the oscillating signal, a transconductive device for providing the resonating device with a positive feedback loop, and a biasing device for providing the transconductive device with a biasing current; and
coupling a capacitive device between a common mode node of the resonating device and a common mode node of the transconductive device.
